(19) United States
(12) Patent Application Publication
(10) Pub. No.: US 2024/0006362 A1
(43) Pub. Date: Jan. 4, 2024

(54) SEMICONDUCTOR DEVICE

(71) Applicant: Samsung Electronics Co., Ltd., Suwon-si (KR)

(72) Inventors: Ju Bin Seo, Suwon-si (KR); Seok Ho Kim, Suwon-si (KR); Kwang Jin Moon, Suwon-si (KR); Ho-Jin Lee, Suwon-si (KR)

(73) Assignee: Samsung Electronics Co., Ltd., Suwon-si (KR)

(21) Appl. No.: 18/155,988

(22) Filed: Jan. 18, 2023

(30) Foreign Application Priority Data
Jul. 4, 2022 (KR) 10-2022-0081630

(51) Int. Cl. H01L 23/00

(52) U.S. Cl. CPC H01L 24/14; H01L 24/05; H01L 24/13; H01L 2224/14519; H01L 2224/1403; H01L 2224/0401; H01L 2224/05546; H01L 2224/13083; H01L 2224/05655; H01L 2224/13155; H01L 2224/13147; H01L 2224/13111; H01L 2224/13139; H01L 2224/13164; H01L 2224/13169; H01L 2224/13144

(57) ABSTRACT

A semiconductor device including a substrate, a wiring pattern in the substrate, a passivation layer on the substrate, the passivation layer and the substrate including a first recess penetrating a part of each of the passivation layer and the substrate and extending toward the wiring pattern, a post connected to the wiring pattern and including a first portion within the first recess and a second portion on the first portion and protruding from a top surface of the passivation layer, a signal bump including a seed layer on the post, a lower bump on the seed layer, and an upper bump on the lower bump, and a heat transfer bump apart from the signal bump, electrically insulated from the wiring pattern, and including another seed layer on the passivation layer, another lower bump on the another seed layer, and another upper bump on the another lower bump may be provided.

### CROSS-REFERENCE TO RELATED APPLICATION

This application claims priority from Korean Patent Application No. 10-2022-0081630 filed on Jul. 4, 2022 in the Korean Intellectual Property Office, and all the benefits accruing therefrom under 35 U.S.C. 119, the contents of which in its entirety are herein incorporated by reference.

### BACKGROUND

### 1. Technical Field

The present disclosure relates to semiconductor devices.

### 2. Description of the Related Art

Recently, as a semiconductor device has become lighter, thinner, and smaller, an external terminal that connects the semiconductor device to an external power source or another semiconductor device is also being reduced in size. Stable implementation of the external terminal helps achieve a reliable semiconductor package fabricated using a semiconductor device. Accordingly, in order to improve the reliability of an external terminal, through which electrical signals are exchanged between the semiconductor device and an external device, various studies are being conducted.

### SUMMARY

Some example embodiments of the present disclosure provide semiconductor devices, each of which reduces a height difference between signal bumps and a heat transfer bump by forming protruding conductive posts protruding at lower portions of the signal bumps. Accordingly, semiconductor devices according to some example embodiments of the present disclosure may mitigate or prevent, in the process of connecting to another semiconductor device, connection failure, reliability degradation, and/or damage of the semiconductor device which are caused by the height difference between the signal bumps and the heat transfer bump.

However, example embodiments of the present disclosure are not restricted to those set forth herein. The above and other aspects of the present disclosure will become more apparent to one of ordinary skill in the art to which the present disclosure pertains by referencing the detailed description of the present disclosure given below.

According to some example embodiments of the present disclosure, a semiconductor device may include a substrate, a wiring pattern disposed in the substrate, a passivation layer disposed on the substrate, the passivation layer and the substrate including a first recess defined therein, the first recess penetrating a part of the passivation layer and a part of the substrate, and extending toward the wiring pattern, a post connected to the wiring pattern, the post including a first portion and a second portion the first portion disposed within the first recess, the second portion disposed on the first portion and protruding from a top surface of the passivation layer in a vertical direction, a signal bump including a first seed layer disposed on the post, a first lower bump disposed on the first seed layer, and a first upper bump disposed on the first lower bump, and a heat transfer bump being spaced apart from the signal bump in a horizontal direction and electrically insulated from the wiring pattern, the heat transfer bump including a second seed layer disposed on the passivation layer, a second lower bump disposed on the second seed layer, and a second upper bump disposed on the second lower bump, wherein a width of the heat transfer bump in the horizontal direction is greater than a width of the signal bump in the horizontal direction.

According to some example embodiments of the present disclosure, a semiconductor device may include a substrate, a wiring pattern disposed in the substrate, a passivation layer disposed on the substrate, the passivation layer and the substrate including a first recess defined therein, the first recess penetrating a part of the passivation layer and a part of the substrate and extending toward the wiring pattern, a first post connected to the wiring pattern and including a first portion and a second portion, the first portion disposed within the first recess and a second portion disposed on the first portion and protruding from a top surface of the passivation layer in a vertical direction, a first signal bump disposed on the first post, and a heat transfer bump disposed on the passivation layer, spaced apart from the first signal bump in a horizontal direction, and electrically insulated from the wiring pattern, wherein a width of the heat transfer bump in the horizontal direction is greater than a width of the first signal bump in the horizontal direction, and wherein a first height from the top surface of the passivation layer to a topmost point of the first signal bump is same as a second height from the top surface of the passivation layer to a topmost point of the heat transfer bump.

According to some example embodiments of the present disclosure, a semiconductor device may include a substrate, a wiring pattern disposed in the substrate, a passivation layer disposed on the substrate, the passivation layer and the substrate including a recess defined therein, the recess penetrating a part of the passivation layer and a part of the substrate and extending toward the wiring pattern, a post connected to the wiring pattern and including a first portion and a second portion, the first portion disposed within the recess and the second portion disposed on the first portion and protruding from a top surface of the passivation layer in a vertical direction, a signal bump including a first seed layer disposed on the post, a first lower bump disposed on the first seed layer, and a first upper bump disposed on the first lower bump, and a heat transfer bump being spaced apart from the signal bump in a horizontal direction and electrically insulated from the wiring pattern, the heat transfer bump including a second seed layer disposed on the passivation layer, a second lower bump disposed on the second seed layer, and a second upper bump disposed on the second lower bump, wherein a width of the heat transfer bump in the horizontal direction is greater than a width of the second portion of the post in the horizontal direction, wherein the post and the first lower bump include a same material, wherein the first seed layer includes a different material from each of the post and the first lower bump, and wherein the second seed layer is lower than a portion of the first seed layer that is disposed on a top surface of the post.

It should be noted that the effects of the present disclosure are not limited to those described above, and other effects of the present disclosure will be apparent from the following description.

### BRIEF DESCRIPTION OF THE DRAWINGS

The above and other aspects and features of the present disclosure will become more apparent by describing in detail some example embodiments thereof with reference to the attached drawings, in which:

FIG. 1 is a schematic plan view of a semiconductor device according to an example embodiment of the present disclosure.

FIG. 2 is a cross-sectional view taken along line A-A′ of FIG. 1.

FIG. 3 is an enlarged view of portion E1 of FIG. 2.

FIGS. 4 to 10 are views illustrating intermediate stages of fabrication, provided to explain a method of fabricating the semiconductor device shown in FIGS. 2 and 3, according to an example embodiment.

FIG. 11 is a cross-sectional view of a semiconductor device according to an example embodiment of the present disclosure.

FIG. 12 is an enlarged view of portion E2 of FIG. 11.

FIG. 13 is a cross-sectional view of a semiconductor device according to an example embodiment of the present disclosure.

FIG. 14 is an enlarged view of portion E3 of FIG. 13.

FIG. 15 is a cross-sectional view of a semiconductor device according to an example embodiment of the present disclosure.

FIG. 16 is an enlarged view of portion E4 of FIG. 15.

FIG. 17 is a cross-sectional view of a semiconductor device according to an example embodiment of the present disclosure.

FIG. 18 is an enlarged view of portion E5 of FIG. 17.

FIGS. 19 to 27 are views illustrating intermediate stages of fabrication, provided to explain a method of fabricating the semiconductor device shown in FIGS. 17 and 18, according to an example embodiment.

FIG. 28 is a cross-sectional view of a semiconductor device according to an example embodiment of the present disclosure.

FIG. 29 is an enlarged view of portion E6 of FIG. 28.

FIG. 30 is a cross-sectional view of a semiconductor device according to an example embodiment of the present disclosure.

FIG. 31 is an enlarged view of portion E7 of FIG. 30.

FIG. 32 is a schematic plan view of a semiconductor device according to an example embodiment of the present disclosure.

FIG. 33 is a cross-sectional view taken along line B-B′ of FIG. 32.

### DETAILED DESCRIPTION

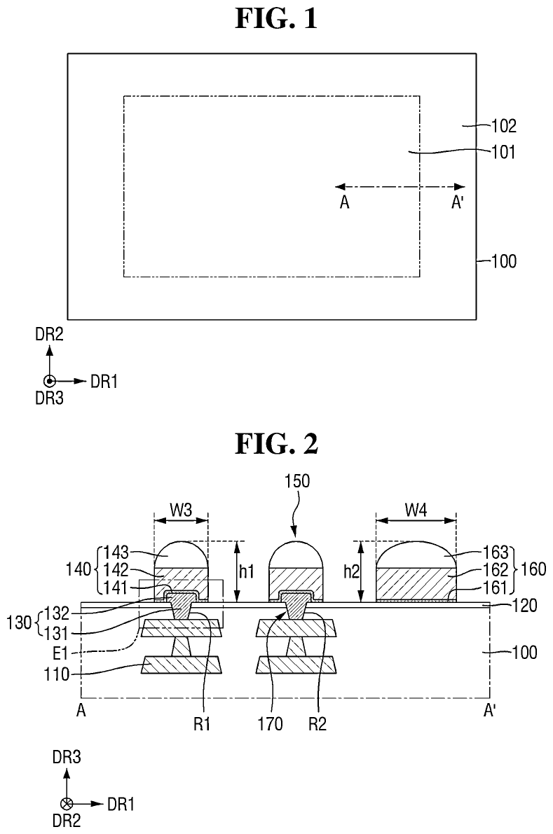

Hereinafter, a semiconductor device according to some example embodiments of the present disclosure will be described with reference to FIGS. 1 to 3.

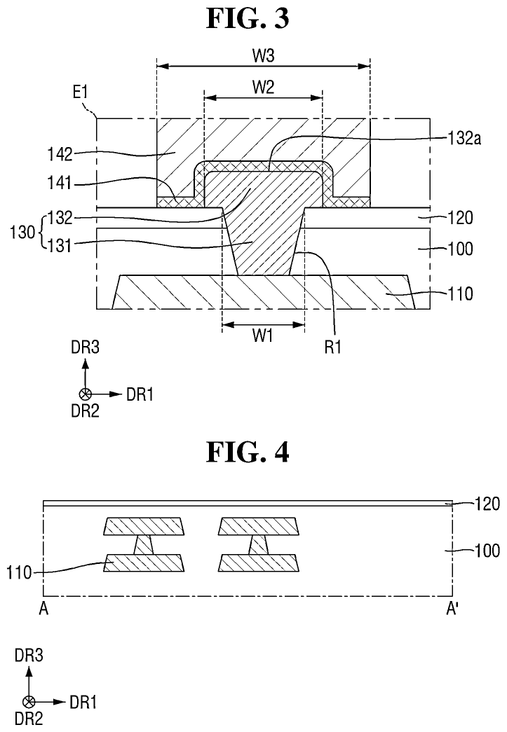

FIG. 1 is a schematic plan view of a semiconductor device according to an example embodiment of the present disclosure. FIG. 2 is a cross-sectional view taken along line A-A′ of FIG. 1. FIG. 3 is an enlarged view of portion E1 of FIG. 2.

Referring to FIGS. 1 to 3, a semiconductor device according to an example embodiment of the present disclosure includes a substrate 100, a wiring pattern 110, a passivation layer 120, a first recess R1, a second recess R2, a first signal bump 140, a second signal bump 150, and a heat transfer bump 160.

The substrate 100 may be a chip when a wafer is divided into a plurality of chips. In some example embodiments, the substrate 100 may be a wafer. When the substrate 100 is a divided chip, the substrate 100 may be, for example, a memory chip, a logic chip, or the like.

When the substrate 100 is a logic chip, the substrate 100 may be designed diversely in consideration of a computation to be performed, etc. When the substrate 100 is a memory chip, the memory chip may be, for example, a non-volatile memory chip.

For example, the memory chip may be a flash memory chip. In some example embodiments, the memory chip may be any one of a NAND flash memory chip or a NOR flash memory chip. However, the present disclosure is not limited thereto. In some example embodiments, the memory chip may include any one of a phase change random access memory (PRAM), a magneto-resistive random access memory (MRAM), or a resistive random access memory (RRAM). In addition, in some example embodiments, when the substrate 100 is a substrate formed on a wafer basis, the substrate 100 may include a logic element or a memory element which performs the same function as described above.

Hereinafter, a first horizontal direction DR1 and a second horizontal direction DR2 are each defined as a direction parallel to a top surface of the substrate 100, and the second horizontal direction DR2 is defined as a direction perpendicular to the first horizontal direction DR1. In addition, a vertical direction DR3 is a direction perpendicular to each of the first and second horizontal directions DR1 and DR2, and is defined as a direction perpendicular to the top surface of the substrate 100.

The substrate 100 may include a first region 101 and a second region 102 in a plane defined by the first horizontal direction DR1 and the second horizontal direction DR2. For example, the first region 101 may be defined as a central region of the substrate 100. The second region 102 may surround the first region 101. That is, the second region 102 may be defined as an edge of the substrate 100.

For example, the first signal bump 140 and the second signal bump 150, which will be described below, may be disposed in the first region 101. The heat transfer bump 160, which will be described below, may be disposed in the second region 102. However, the present disclosure is not limited thereto. In some example embodiments, the heat transfer bump 160 may be disposed in each of the first region 101 and the second region 102.

The wiring pattern 110 may be disposed within the substrate 100. The wiring pattern 110 may include a plurality of lines that are spaced apart from one another in each of the first horizontal direction DR1, the second horizontal direction DR2, and the vertical direction DR3. In addition, the wiring pattern 110 may include a plurality of vias that extend in the vertical direction DR3 to provide connections between the plurality of lines. For example, an uppermost line among the plurality of lines may be buried within the substrate 100. However, the present disclosure is not limited thereto. In some example embodiments, a top surface of the uppermost line among the plurality of lines may be exposed to the top surface of the substrate 100. For example, the wiring pattern 110 may be electrically connected to a circuit pattern formed in the substrate 100.

For example, a width in the first horizontal direction DR1 of the wiring pattern 110 may decrease toward the top surface of the substrate 100. However, the present disclosure is not limited thereto. The wiring pattern 110 may include a conductive material. The wiring pattern 110 may include, for example, metal (e.g., aluminum (Al)), but the present disclosure is not limited thereto.

The passivation layer 120 may be disposed on the top surface of the substrate 100. For example, the passivation layer 120 may be formed in a conformal manner. However, the present disclosure is not limited thereto. The passivation layer 120 may include an insulating material. The passivation layer 120 may include, for example, a nitride film or an oxide film.

Each of the first recess R1 and the second recess R2 may penetrate a part of the passivation layer 120 and a part of the substrate 100 in the vertical direction DR3 and extend toward the wiring pattern 110. The second recess R2 may be spaced apart from the first recess R1 in the first horizontal direction DR1.

A first post 130 may be disposed within the first recess R1. In addition, at least a part of the first post 130 may protrude from the top surface of the passivation layer 120 in the vertical direction DR3. For example, the first post 130 may include a first portion 131 and a second portion 132.

The first portion 131 of the first post 130 may be disposed within the first recess R1. For example, the first portion 131 of the first post 130 may completely fill the inside of the first recess R1. The first portion 131 of the first post 130 may be connected to the wiring pattern 110. For example, a width in the first horizontal direction DR1 of the first portion 131 of the first post 130 may decrease toward the wiring pattern 110.

The second portion 132 of the first post 130 may be disposed on the first portion 131 of the first post 130. The second portion 132 of the first post 130 may protrude from the top surface of the passivation layer 120 in the vertical direction DR3. At least a part of the second portion 132 of the first post 130 may be in contact with the top surface of the passivation layer 120. For example, at least a part of the second portion 132 of the first post 130 may be disposed on the top surface of the passivation layer 120 above both sidewalls of the first portion 131 of the first post 130 in the first horizontal direction DR1.

For example, a width W2 of the second portion 132 of the first post 130 in the first horizontal direction may be greater than a width W1 of the first portion 131 of the first post 130 in the first horizontal direction DR1. The first post 130 may include a conductive material. The first post 130 may include, for example, nickel (Ni). However, the present disclosure is not limited thereto. In some other example embodiments, the first post 130 may include at least one of, for example, copper (Cu), palladium (Pd), platinum (Pt), gold (Au), or a combination thereof.

A second post 170 may be disposed within the second recess R2. In addition, at least a part of the second post 170 may protrude from the top surface of the passivation layer 120 in the vertical direction DR3. For example, the second post 170 may be spaced apart from the first post 130 in the first horizontal direction DR1. The second post 170 may have the same structure as that of the first post 130. Thus, a detailed description of the second post 170 will not be provided. The second post 170 may include the same material as that of the first post 130.

The first signal bump 140 may be disposed on the first region 101, which is the central region of the substrate 100. The first signal bump 140 may be disposed on the first post 130 and the passivation layer 120. For example, the first signal bump 140 may cover sidewalls and a top surface 132a of the second portion 132 of the first post 130 on the passivation layer 120. For example, the first signal bump 140 may be in contact with the top surface of the passivation layer 120 and each of the sidewalls and top surface 132a of the second portion 132 of the first post 130. The first signal bump 140 may be electrically connected to the wiring pattern 110 through the first post 130.

For example, a width W3 of the first signal bump 140 in the first horizontal direction DR1 may be greater than a width W2 of the first post 130 in the first horizontal direction DR1. For example, the width W3 of the first signal bump 140 in the first horizontal direction DR1 may be greater than the width W2 of the second portion 132 of the first post 130 in the first horizontal direction DR1.

The first signal bump 140 may include a first seed layer 141, a first lower bump 142, and a first upper bump 143. The first seed layer 141 may constitute a bottom surface of the first signal bump 140. The first seed layer 141 may be in contact with the top surface of the passivation layer 120 and each of the sidewalls and top surface 132a of the second portion 132 of the first post 130. For example, the first seed layer 141 may be formed in a conformal manner.

The first seed layer 141 may include a conductive material. For example, the first seed layer 141 may include a different material from that of the first post 130. The first seed layer 141 may include, for example, copper (Cu). However, when the first post 130 includes copper (Cu), the first seed layer 141 may include the same material as that of the first post 130.

The first lower bump 142 may be disposed on the first seed layer 141. The first lower bump 142 may be in contact with the first seed layer 141. For example, the first lower bump 142 may completely overlap the first seed layer 141 in the vertical direction DR3. That is, the sidewalls of the first lower bump 142 may be aligned with the sidewalls of the first seed layer 141 in the vertical direction DR3. The first lower bump 142 may lie on the first seed layer 141 and cover the sidewalls and top surface 132a of the second portion 132 of the first post 130. For example, at least a part of the first lower bump 142 may overlap the second portion 132 of the first post 130 in the first horizontal direction DR1.

For example, a top surface of the first lower bump 142 may be flat. However, the present disclosure is not limited thereto. For example, a width W3 of the first lower bump 142 in the first horizontal direction DR1 may be greater than a width W2 of the second portion 132 of the first post 130 in the first horizontal direction DR1. For example, the first lower bump 142 may be formed as a single film. However, the present disclosure is not limited thereto. In some other example embodiments, the first lower bump 142 may be formed as a multi-film.

The first lower bump 142 may include a conductive material. For example, the first lower bump 142 may include the same material as that of the first post 130, but the present disclosure is not limited thereto. For example, the first lower bump 142 may include a different material from that of the first seed layer 141, but the present disclosure is not limited thereto.

For example, when the first lower bump 142 is formed as a single film, the first lower bump 142 may include nickel (Ni). However, the present disclosure is not limited thereto. In some other example embodiments, the first lower bump 142 may include at least one of, for example, copper (Cu), palladium (Pd), platinum (Pt), gold (Au), or a combination thereof. For example, when the first lower bump 142 is formed as a multi-film, the first lower bump 142 may include at least two of nickel (Ni), copper (Cu), palladium (Pd), platinum (Pt), gold (Au), or a combination thereof.

The first upper bump 143 may be disposed on the first lower bump 142. The first upper bump 143 may be in contact with the first lower bump 142. For example, the first upper bump 143 may have a hemispherical shape, but the present disclosure is not limited thereto. The first upper bump 143 may include a conductive material. The first upper bump 143 may include, for example, a solder paste or a metal paste. The first upper bump 143 may include at least one of, for example, copper (Cu), tin (Sn), silver (Ag), or a combination thereof.

The second signal bump 150 may be disposed on the first region 101, which is the central region of the substrate 100. The second signal bump 150 may be disposed on the second post 170 and the passivation layer 120. The second signal bump 150 may be spaced apart from the first signal bump 140 in the first horizontal direction DR1. For example, the second signal bump 150 may cover sidewalls and a top surface of a portion protruding in the vertical direction DR3 on the top surface of the passivation layer 120. The second signal bump 150 may be electrically connected to the wiring pattern 110 through the second post 170.

For example, a width in the first horizontal direction DR1 of the second signal bump 150 may be identical to the width W3 in the first horizontal direction DR1 of the first signal bump 140. In addition, a height in the vertical direction DR3 from the top surface of the passivation layer 120 to the topmost point of the second signal bump 150 may be the same as a first height h1 in the vertical direction DR3 from the top surface of the passivation layer 120 to the topmost point of the first signal bump 140. The second signal bump 150 may have the same structure as that of the first signal bump 140. Thus, a detailed description of the second signal bump 150 will not be provided. The second signal bump 150 may include the same material as that of the first signal bump 140.

The heat transfer bump 160 may be disposed on the second region 102, which is an edge of the substrate 100. The heat transfer bump 160 may be disposed on the passivation layer 120. For example, the heat transfer bump 160 may be spaced apart from the second signal bump 150 in the first horizontal direction DR1. For example, a lower surface of the heat transfer bump 160 may entirely contact with the top surface of the passivation layer 120. The passivation layer 120 may be disposed between the heat transfer bump 160 and the substrate 100. However, the present disclosure is not limited thereto. In some example embodiments, the heat transfer bump 160 may be in contact with the top surface of the substrate 100.

The heat transfer bump 160 may be electrically insulated from the wiring pattern 110. The heat transfer bump 160 may serve to dissipate heat generated within the substrate 100 to the outside of the substrate 100. That is, the heat transfer bump 160 may have an increased area of the lower surface facing the top surface of the substrate 100, thereby increasing the heat dissipation effect. For example, a width W4 of the heat transfer bump 160 in the first horizontal direction DR1 may be greater than the width W3 of the first signal bump 140 in the first horizontal direction DR1.

For example, a second height h2 in the vertical direction DR3 from the top surface of the passivation layer 120 to the topmost point of the heat transfer bump 160 may be the same as the first height h1 in the vertical direction DR3 from the top surface of the passivation layer 120 to the topmost point of the first signal bump 140. That is, the first height h1 of the first signal bump 140 in the vertical direction DR3, the height of the second signal bump 150 in the vertical direction DR3, and the second height h2 of the heat transfer bump 160 in the vertical direction DR3 may be the same as one another.

The heat transfer bump 160 may include a second seed layer 161, a second lower bump 162, and a second upper bump 163. The second seed layer 161 may constitute a bottom surface of the heat transfer bump 160. An entirety of the second seed layer 161 may be in contact with the top surface of the passivation layer 120. For example, the second seed layer 161 may be formed in a conformal manner. For example, the second seed layer 161 may be higher than the top surface of the substrate 100. However, the present disclosure is not limited thereto.

The second seed layer 161 may have a step difference (e.g., a height difference) with respect to a portion of the first seed layer 141 that is disposed on the top surface of the first post 130. For example, the second seed layer 161 may be formed to be lower than a portion the first seed layer 141 that is disposed on the top surface of the second portion 132 of the first post 130. The second seed layer 161 may include a conductive material. For example, the second seed layer 161 may include the same material as that of the first seed layer 141. The second seed layer 161 may include, for example, copper (Cu).

The second lower bump 162 may be disposed on the second seed layer 161. The second lower bump 162 may be in contact with the second seed layer 161. For example, the second lower bump 162 may completely overlap the second seed layer 161 in the vertical direction DR3. That is, sidewalls of the second lower bump 162 may be aligned with sidewalls of the second seed layer 161 in the vertical direction DR3.

For example, a lower surface of the second lower bump 162 may be flat. A top surface of the second lower bump 162 may be flat. However, the present disclosure is not limited thereto. For example, the width W4 of the second lower bump 162 in the first horizontal direction DR1 may be greater than the width W3 of the first lower bump 142 in the first horizontal direction DR1. For example, the second lower bump 162 may be formed as a single film. However, the present disclosure is not limited thereto. In some other example embodiments, the second lower bump 162 may be formed as a multi-film.

The second lower bump 162 may include a conductive material. For example, the second lower bump 162 may include the same material as that of the first lower bump 142. For example, the second lower bump 162 may include a different material from that of the second seed layer 161, but the present disclosure is not limited thereto.

For example, when the second lower bump 162 is formed as a single film, the second lower bump 162 may include nickel (Ni). However, the present disclosure is not limited thereto. In some other example embodiments, the second lower bump 162 may include at least one of, for example, copper (Cu), palladium (Pd), platinum (Pt), gold (Au), or a combination thereof. For example, when the second lower bump 162 is formed as a multi-film, the second lower bump 162 may include at least two of nickel (Ni), copper (Cu), palladium (Pd), platinum (Pt), gold (Au), or a combination thereof.

The second upper bump 163 may be disposed on the second lower bump 162. The second upper bump 163 may be in contact with the second lower bump 162. For example, the second upper bump 163 may have a hemispherical shape, but the present disclosure is not limited thereto. The second upper bump 163 may include a conductive material. For example, the second upper bump 163 may include the same material as that of the first upper bump 143. The second upper bump 163 may include, for example, a solder paste or a metal paste. The second upper bump 163 may include at least one of, for example, copper (Cu), tin (Sn), silver (Ag), or a combination thereof.

For example, the second height h2 in the vertical direction DR3 from the top surface of the passivation layer 120 to the topmost point of the second upper bump 163 may be the same as the first height h1 in the vertical direction DR3 from the top surface of the passivation layer 120 to the topmost point of the first upper bump 143.

The semiconductor device according to some example embodiments of the present disclosure may have the conductive posts 130 and 170 protruding at the lower portions of the signal bumps 140 and 150, thereby reducing the height difference between the signal bumps 140 and 150 and the heat transfer bump 160. Accordingly, the semiconductor device according to some example embodiments of the present disclosure may mitigate or prevent, in the process of connecting to another semiconductor device, connection failure, reliability degradation, and damage of the semiconductor device which are caused by the height difference between the signal bumps 140 and 150 and the heat transfer bump 160.

Hereinafter, a method of fabricating the semiconductor device shown in FIGS. 2 and 3 will be described with reference to FIGS. 2 to 10.

FIGS. 4 to 10 are views illustrating intermediate stages of fabrication, provided to explain a method of fabricating the semiconductor device shown in FIGS. 2 and 3, according to an example embodiment.

Referring to FIG. 4, the wiring pattern 110, which includes a plurality of lines and a plurality of vias, may be formed in the substrate 100. For example, an uppermost line among the plurality of lines may be buried within the substrate 100. However, the present disclosure is not limited thereto. In some example embodiments, a top surface of the uppermost line among the plurality of lines may be exposed to the top surface of the substrate 100.

Thereafter, the passivation layer 120 may be formed on the top surface of the substrate 100. For example, the passivation layer 120 may entirely cover the top surface of the substrate 100. For example, the passivation layer 120 may be formed in a conformal manner, but the present disclosure is not limited thereto.

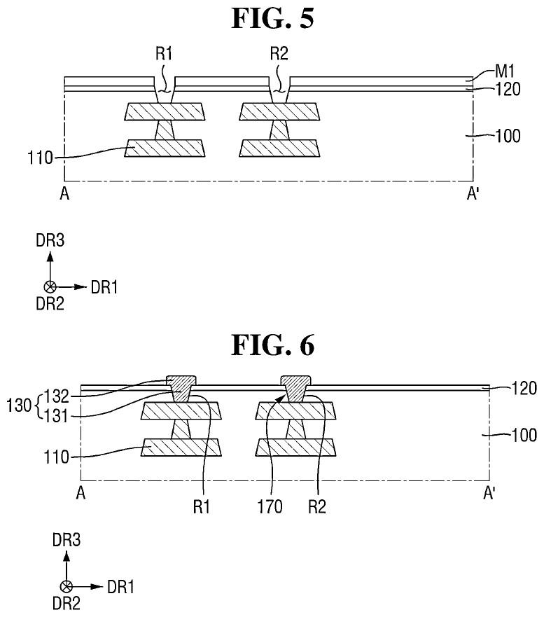

Referring to FIG. 5, a first mask pattern M1 may be formed on the top surface of the passivation layer 120. The first mask pattern M1 may open a portion that overlaps the wiring pattern 110 in the vertical direction DR3.

Then, the passivation layer 120 and the substrate 100 may be partially etched using the first mask pattern M1 as a mask, thereby exposing the wiring pattern 110. By the etching process, the first recess R1 and the second recess R2 that each penetrate a part of the passivation layer 120 and a part of the substrate 100 in the vertical direction DR3 may be formed. For example, the second recess R2 may be spaced apart from the first recess R1 in the first horizontal direction DR1. The wiring pattern 110 may be exposed by a corresponding one of the first recess R1 and the second recess R2.

Referring to FIG. 6, the first mask pattern M1 may be removed. Thereafter, the first post 130 may be formed in the first recess R1. In addition, the second post 170 may be formed in the second recess R2. The first post 130 and the second post 170 may be formed by the same process.

For example, each of the first post 130 and the second post 170 may be formed by an electroless plating process. However, the present disclosure is not limited thereto.

At least a part of the first post 130 may protrude further than the top surface of the passivation layer 120 in the vertical direction DR3. For example, the first post 130 may include the first portion 131 and the second portion 132. The first portion 131 may fill the inside of the first recess R1 and the second portion 132 may be on the first portion 131 and may protrude further than the top surface of the passivation layer 120 in the vertical direction DR3.

For example, the width of the second portion 132 of the first post 130 in the first horizontal direction DR1 may be greater than the width of the first portion 131 of the first post 130 in the first horizontal direction DR1. That is, at least a part of the second portion 132 of the first post 130 may be formed in contact with the top surface of the passivation layer 120. The second post 170 may be formed with the same structure as the first post 130.

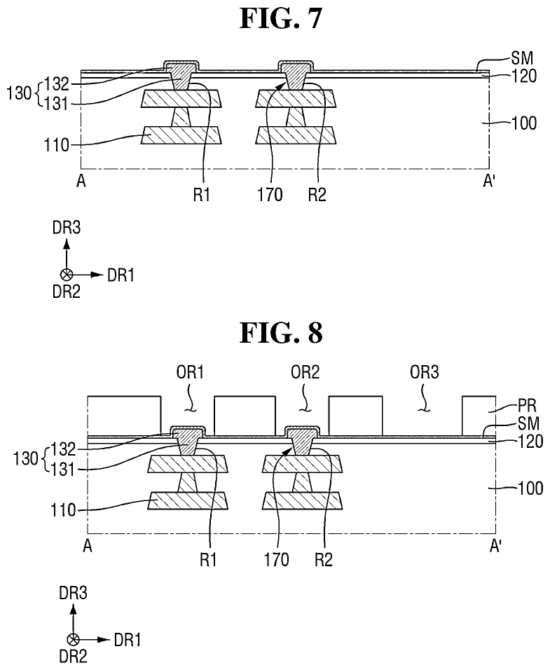

Referring to FIG. 7, a seed material layer SM may be formed on each of the top surface of the passivation layer 120, the sidewalls and top surface of the first post 130 exposed to the top surface of the passivation layer 120, and the sidewalls and top surface of the second post 170 exposed to the upper surface of the passivation layer 120. For example, the seed material layer SM may be conformally formed. For example, the seed material layer SM may include, for example, copper (Cu).

Referring to FIG. 8, a photoresist pattern PR may be formed on the top surface of the seed material layer SM. The photoresist pattern PR may open a portion that overlaps each of the first post 130 and the second post 170 in the vertical direction DR3. For example, the photoresist pattern PR may expose a part of the seed material layer SM formed adjacent to each of the first post 130 and the second post 170 on the top surface of the passivation layer 120. Accordingly, a first open region OR1 may be formed on the first post 130, and a second open region OR2 may be formed on the second post 170. In addition, the photoresist pattern PR may expose the seed material layer SM in a portion where the heat transfer bump 160 shown in FIG. 2 is to be formed. Accordingly, a third open region OR3 may be formed in the portion where the heat transfer bump 160 shown in FIG. 2 is to be formed.

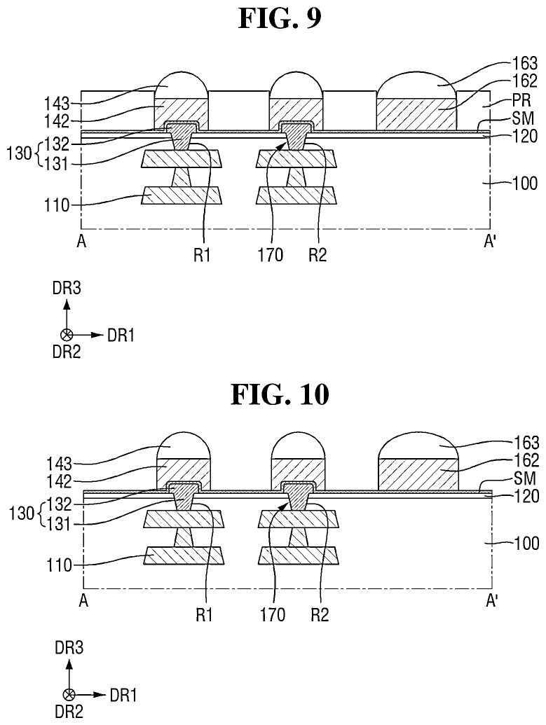

Referring to FIG. 9, the first lower bump 142 and the first upper bump 143 may be sequentially formed in each of the first open region OR1 and the second open region OR2. In addition, the second lower bump 162 and the second upper bump 163 may be sequentially formed in the third open region OR3.

For example, the first lower bump 142 and the second lower bump 162 may be formed by the same process. For example, the first lower bump 142 and the second lower bump 162 may be formed by an electrolytic plating process. However, the present disclosure is not limited thereto. For example, the first upper bump 143 and the second upper bump 163 may be formed by the same process.

Referring to FIG. 10, the photoresist pattern PR may be removed. Accordingly, the seed material layer SM formed on a portion that does not overlap each of the first lower bump 142 and the second lower bump 162 in the vertical direction DR3 may be exposed.

Referring to FIGS. 2 and 3, the seed material layer SM (e.g., in FIG. 10) formed on the portion that does not overlap each of the first lower bump 142 and the second lower bump 162 in the vertical direction DR3 may be etched. After the etching process is performed, the seed material layer SM (e.g., in FIG. 10) remaining at the lower portion of the first lower bump 142 may be defined as the first seed layer 141 and the seed material layer SM (e.g., in FIG. 10) remaining at the lower portion of the second lower bump 162 may be defined as the second seed layer 161. By the fabricating process, the semiconductor device shown in FIGS. 2 and 3 may be fabricated.

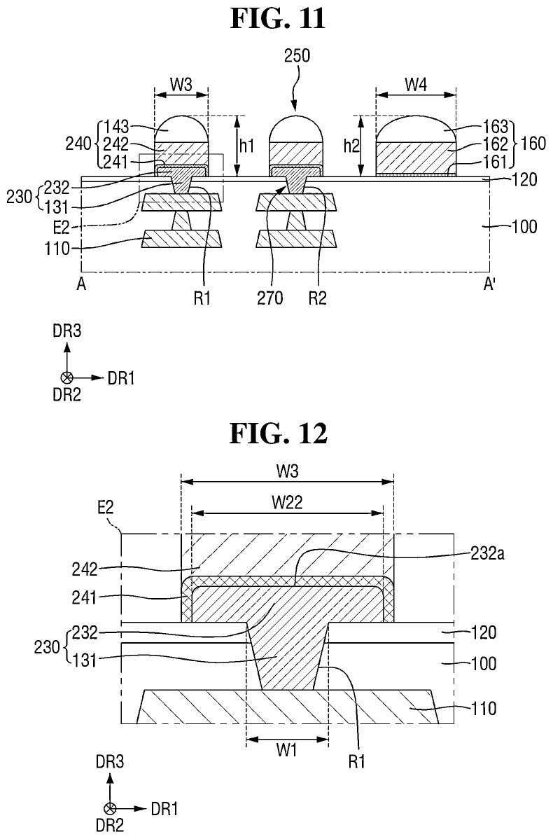

Hereinafter, a semiconductor device according to another example embodiment of the present disclosure will be described with reference to FIGS. 11 and 12. A description will be given focusing on differences from the semiconductor device shown in FIGS. 1 to 3.

FIG. 11 is a cross-sectional view of a semiconductor device according to an example embodiment of the present disclosure. FIG. 12 is an enlarged view of portion E2 of FIG. 11.

Referring to FIGS. 11 and 12, in a semiconductor device according to an example embodiment of the present disclosure, a first seed layer 214 disposed on sidewalls of a second portion 232 of a first post 230 may be exposed.

For example, the first post 230 may include a first portion 131 disposed in a first recess R1 and the second portion 232 which lies on the first portion 131 and protrudes from a top surface of a passivation layer 120 in the vertical direction DR3. For example, a width W3 of a first signal bump 240 in the first horizontal direction DR1 may be greater than a width W22 of the second portion 232 of the first post 230 in the first horizontal direction DR1. The second post 270 may be disposed within a second recess R2. The second post 270 may have the same structure as that of the first post 230.

A first seed layer 241 may cover the sidewalls and top surface 232a of the second portion 232 of the first post 230. For example, sidewalls of the first seed layer 241 disposed on the sidewalls of the second portion 232 of the first post 230 may be exposed. Although FIG. 12 illustrates that the first seed layer 241 disposed on the sidewalls of the second portion 232 of the first post 230 may be aligned with sidewalls of a first lower bump 242 in the vertical direction DR3, the present disclosure is not limited thereto. In some other example embodiments, the sidewalls of the first seed layer 241 disposed on the sidewalls of the second portion 232 of the first post 230 may be recessed toward the second portion 232 of the first post 230. A second signal bump 250 may be disposed on the second post 270. The second signal bump 250 may have the same structure as that of the first signal bump 240.

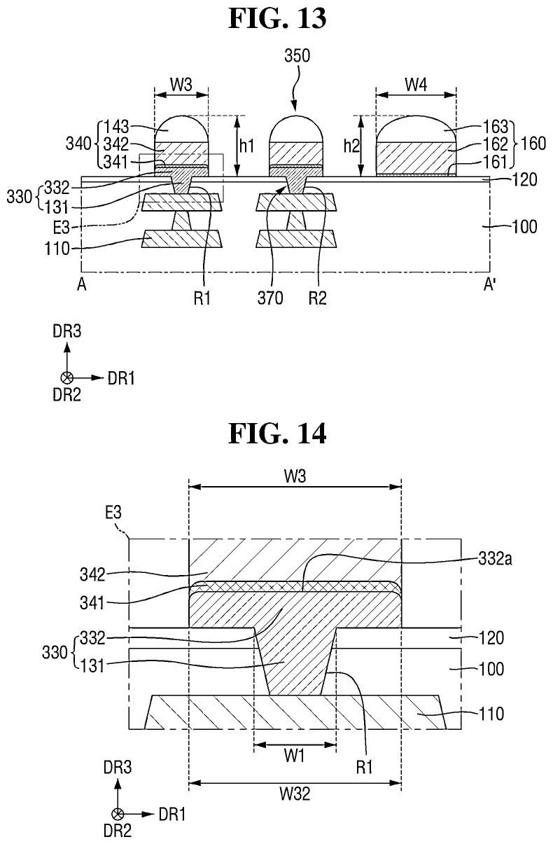

A semiconductor device according to an example embodiment of the present disclosure will be described hereinafter with reference to FIGS. 13 and 14. A description will be given focusing on differences from the semiconductor device shown in FIGS. 1 to 3.

FIG. 13 is a cross-sectional view of a semiconductor device according to an example embodiment of the present disclosure. FIG. 14 is an enlarged view of portion E3 of FIG. 13.

Referring to FIGS. 13 and 14, in a semiconductor device according to an example embodiment of the present disclosure, sidewalls of a second portion 332 of a first post 330 may be exposed.

For example, the first post 330 may include a first portion 131 disposed in a first recess R1 and the second portion 332 which lies on the first portion 131 and protrudes from a top surface of a passivation layer 120 in the vertical direction DR3. For example, a width W3 of a first signal bump 340 in the first horizontal direction DR1 may be the same as a width W32 of the second portion 332 of the first post 330 in the first horizontal direction DR1. For example, the sidewalls of the second portion 332 of the first post 330 may be aligned with sidewalls of a first lower bump 342 in the vertical direction DR3. A second post 370 may be disposed within a second recess R2. The second post 370 may have the same structure as that of the first post 330.

A first seed layer 341 may cover the sidewalls and top surface 332a of the second portion 332 of the first post 330. Although FIG. 14 illustrates that sidewalls of the first seed layer 341 are aligned respectively with sidewalls of a first lower bump 342 and the sidewalls of the second portion 332 of the first post 330 in the vertical direction DR3, the present disclosure is not limited thereto. In some other example embodiments, the sidewalls of the first seed layer 341 may be recessed toward the center of the first signal bump 240. A second signal bump 350 may be disposed on the second post 370. The second signal bump 350 may have the same structure as that of the first signal bump 340.

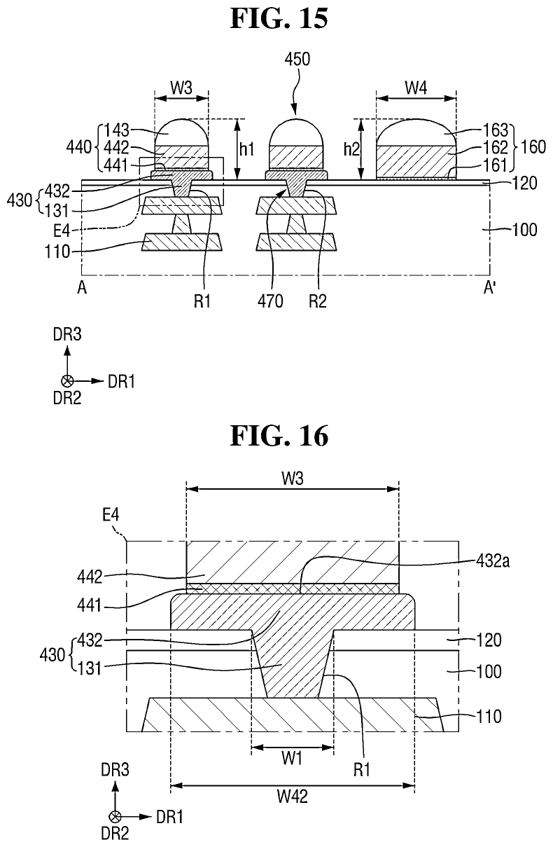

A semiconductor device according to an example embodiment of the present disclosure will be described hereinafter with reference to FIGS. 15 and 16. A description will be given focusing on differences from the semiconductor device shown in FIGS. 1 to 3.

FIG. 15 is a cross-sectional view of a semiconductor device according to an example embodiment of the present disclosure. FIG. 16 is an enlarged view of portion E4 of FIG. 15.

Referring to FIGS. 15 and 16, in a semiconductor device according to an example embodiment of the present disclosure, at least a part of a top surface of a second portion 432 of a first post 430 may protrude past sidewalls of a first lower bump 442 when viewed in a plan view such that a sidewall of the second portion 432 may be exposed.

For example, the first post 430 may include a first portion 131 disposed in a first recess R1 and the second portion 432 which lies on the first portion 131 and protrudes from a top surface of a passivation layer 120 in the vertical direction DR3. For example, a width W3 of a first signal bump 440 in the first horizontal direction DR1 may be smaller than a width W42 of the second portion 432 of the first post 430 in the first horizontal direction DR1. For example, the sidewalls of the second portion 432 of the first post 430 may be exposed. In addition, a part of the top surface of the second portion 432 of the first post 430 adjacent to the sidewall of the second portion 432 of the first post 430 may be exposed. A second post 470 may be disposed within a second recess R2. The second post 470 may have the same structure as that of the first post 430.

A first seed layer 441 may cover a top surface 432a of the second portion 432 of the first post 430. Although FIG. 16 illustrates that sidewalls of the first seed layer 441 are aligned with sidewalls of a first lower bump 442, respectively, in the vertical direction DR3, the present disclosure is not limited thereto. In some other example embodiments, the sidewalls of the first seed layer 441 may be recessed toward the center of the first signal bump 440. A second signal bump 450 may be disposed on the second post 470. The second signal bump 450 may have the same structure as that of the first signal bump 440.

Hereinafter, a semiconductor device according to an example embodiment of the present disclosure will be described hereinafter with reference to FIGS. 15 and 16. A description will be given focusing on differences from the semiconductor device shown in FIGS. 1 to 3.

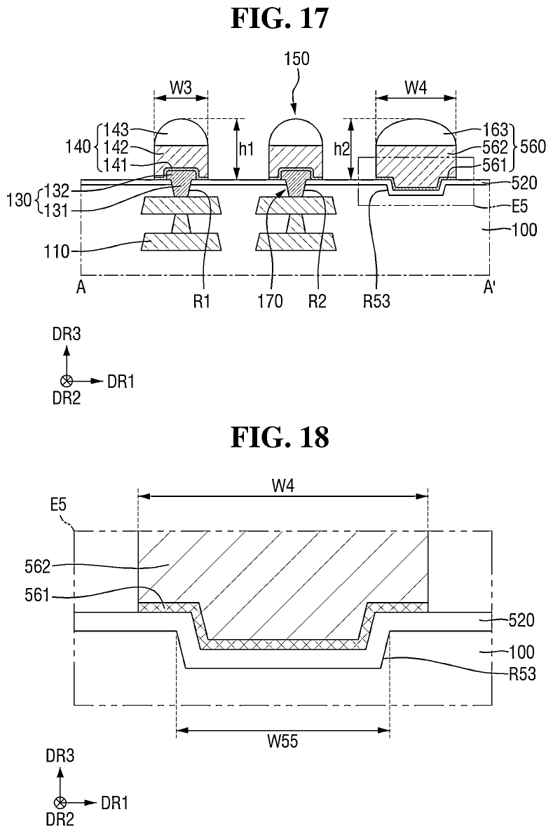

FIG. 17 is a cross-sectional view of a semiconductor device according to an example embodiment of the present disclosure. FIG. 18 is an enlarged view of portion E5 of FIG. 17.

Referring to FIGS. 17 and 18, in a semiconductor device according to an example embodiment of the present disclosure, a third recess R53 may be formed under a heat transfer bump 560 and at least a part of the heat transfer bump 560 may be disposed within the third recess R53.

For example, under the lower portion of the heat transfer bump 560, the third recess R53 may be formed to be recessed inwardly from a top surface of a substrate 100. That is, a bottom surface of the third recess R53 may be formed lower than the top surface of the substrate 100. For example, a width W4 of the heat transfer bump 560 in the first horizontal direction DR1 may be greater than a width W55 of the third recess R53 in the first horizontal direction DR1. At least a part of the heat transfer bump 560 may be disposed on a top surface of a passivation layer 520 adjacent to the third recess R53.

The passivation layer 520 may be disposed on the top surface of the substrate 100. Also, the passivation layer 520 may be disposed along sidewalls and a bottom surface of the third recess R53. A second seed layer 561 may be disposed on the passivation layer 520 in the third recess R53. In addition, the second seed layer 561 may be disposed on the top surface of the passivation layer 520 adjacent to the third recess R53. A second lower bump 562 may be disposed on the second seed layer 561. For example, at least a part of the second lower bump 562 may be disposed within the third recess R53.

Hereinafter, a method of fabricating the semiconductor device shown in FIGS. 17 and 18 will be described with reference to FIGS. 17 to 27.

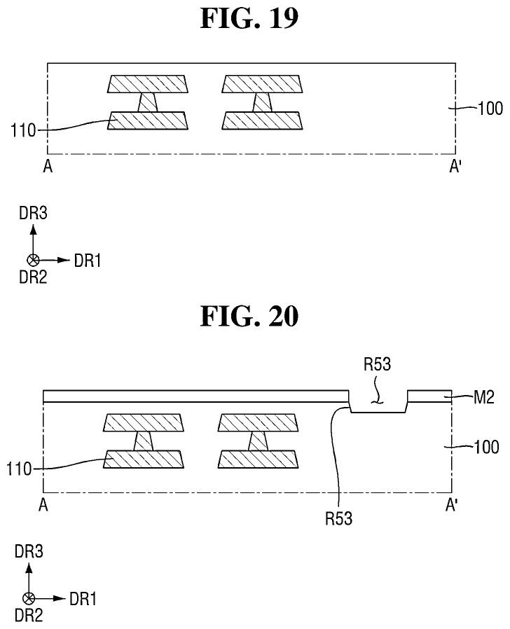

FIGS. 19 to 27 are views illustrating intermediate stages of fabrication, provided to explain a method of fabricating the semiconductor device shown in FIGS. 17 and 18, according to an example embodiment.

Referring to FIG. 19, a wiring pattern 110, which includes a plurality of lines and a plurality of vias, may be formed in the substrate 100. For example, an uppermost line among the plurality of lines may be buried within the substrate 100. However, the present disclosure is not limited thereto. In some example embodiments, a top surface of the uppermost line among the plurality of lines may be exposed to the top surface of the substrate 100.

Referring to FIG. 20, a second mask pattern M2 may be formed on the top surface of the substrate 100. The second mask pattern M2 may open the top surface of the substrate 100 in a portion where the heat transfer bump 560 shown in FIG. 17. Thereafter, the substrate 100 may be partially etched using the second mask pattern M2 as a mask to form the third recess R53.

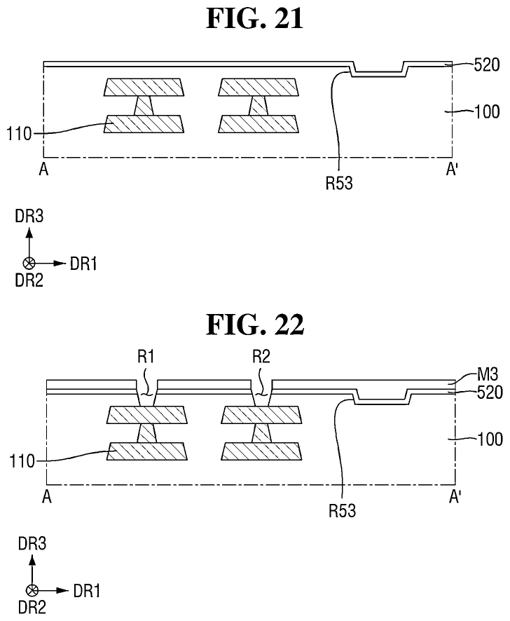

Referring to FIG. 21, the second mask pattern M2 may be removed. Then, the passivation layer 520 may be formed along the top surface of the substrate 100 and the sidewalls and the bottom surface of the third recess R53. For example, the passivation layer 520 may be formed in a conformal manner, but the present disclosure is not limited thereto.

Referring to FIG. 22, a third mask pattern M3 may be formed on the top surface of the passivation layer 520. For example, the third mask pattern M3 may fill the inside of the third recess R3. The third mask pattern M3 may open a portion that overlaps the wiring pattern 110 in the vertical direction DR3.

Then, the passivation layer 320 and the substrate 100 may be partially etched using the third mask pattern M3 as a mask, thereby exposing the wiring pattern 110. By the etching process, the first recess R1 and the second recess R2 that each penetrate a part of the passivation layer 320 and a part of the substrate 100 in the vertical direction DR3 may be formed. For example, the second recess R2 may be spaced apart from the first recess R1 in the first horizontal direction DR1. The wiring pattern 110 may be exposed by each of the first recess R1 and the second recess R2.

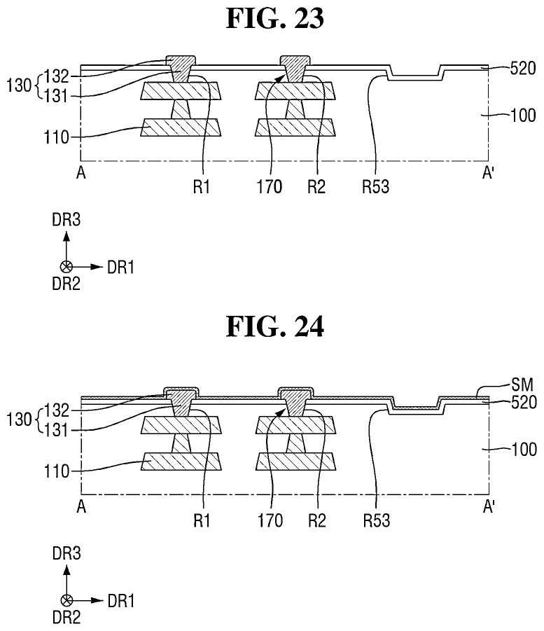

Referring to FIG. 23, the third mask pattern M3 may be removed. Thereafter, the first post 130 may be formed in the first recess R1. In addition, the second post 170 may be formed in the second recess R2. The first post 130 and the second post 170 may be formed by the same process.

For example, each of the first post 130 and the second post 170 may be formed by an electroless plating process. However, the present disclosure is not limited thereto.

At least a part of the first post 130 may be formed to protrude further than the top surface of the passivation layer 520 in the vertical direction DR3. For example, the first post 130 may include the first portion 131 and the second portion 132. The first portion 131 may fill the inside of the first recess R1 and the second portion 132 may be on the first portion 131 and may protrude further than the top surface of the passivation layer 520 in the vertical direction DR3.

For example, the width of the second portion 132 of the first post 130 in the first horizontal direction DR1 may be greater than the width of the first portion 131 of the first post 130 in the first horizontal direction DR1. That is, at least a part of the second portion 132 of the first post 130 may contact the top surface of the passivation layer 520. The second post 170 may be formed with the same structure as the first post 130.

Referring to FIG. 24, a seed material layer SM may be formed on each of the top surface of the passivation layer 520, the sidewalls and top surface of the first post 130 exposed to the top surface of the passivation layer 520, the sidewalls and top surface of the second post 170 exposed to the upper surface of the passivation layer 520, and the passivation layer 520 formed in the third recess R3. For example, the seed material layer SM may be conformally formed. For example, the seed material layer SM may include, for example, copper (Cu).

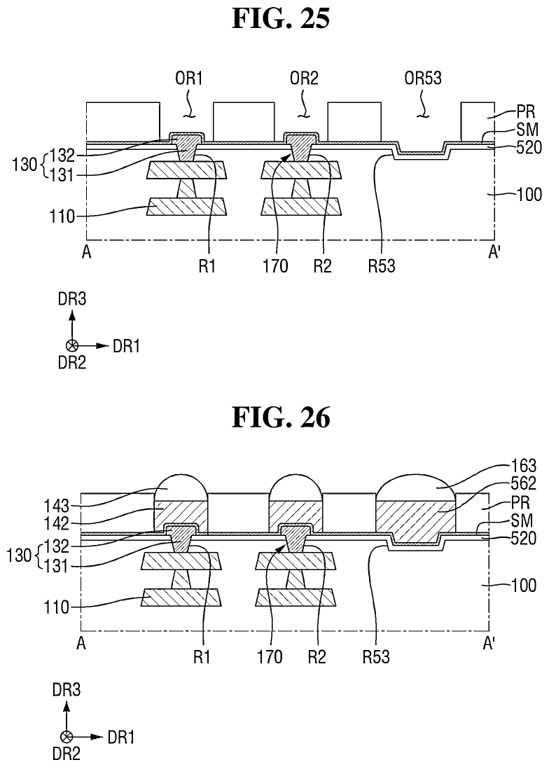

Referring to FIG. 25, a photoresist pattern PR may be formed on the top surface of the seed material layer SM. The photoresist pattern PR may open a portion that overlaps each of the first post 130, the second post 170, and the third recess R53 in the vertical direction DR3. For example, the photoresist pattern PR may expose a part of the seed material layer SM formed adjacent to each of the first post 130, the second post 170, the third recess R53 on the top surface of the passivation layer 120. Accordingly, a first open region OR1 may be formed on the first post 130, a second open region OR2 may be formed on the second post 170, a third open region OR53 may be formed on the third recess R53.

Referring to FIG. 26, the first lower bump 142 and the first upper bump 143 may be sequentially formed in each of the first open region OR1 and the second open region OR2. In addition, the second lower bump 562 and the second upper bump 163 may be sequentially formed in the third open region OR53.

For example, the first lower bump 142 and the second lower bump 562 may be formed by the same process. For example, the first lower bump 142 and the second lower bump 562 may be formed by an electrolytic plating process. However, the present disclosure is not limited thereto. For example, the first upper bump 143 and the second upper bump 163 may be formed by the same process.

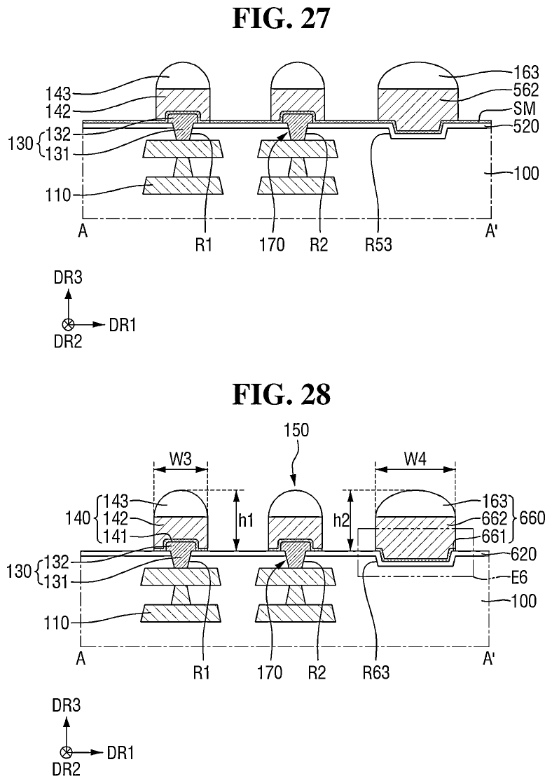

Referring to FIG. 27, the photoresist pattern PR may be removed. Accordingly, the seed material layer SM formed on a portion that does not overlap each of the first lower bump 142 and the second lower bump 562 in the vertical direction DR3 may be exposed.

Referring to FIGS. 17 and 18, the seed material layer SM (e.g., in FIG. 27) formed on the portion that does not overlap each of the first lower bump 142 and the second lower bump 562 in the vertical direction DR3 may be etched. After the etching process is performed, the seed material layer SM (e.g., in FIG. 27) remaining at the lower portion of the first lower bump 142 may be defined as the first seed layer 141 and the seed material layer SM (e.g., in FIG. 27) remaining at the lower portion of the second lower bump 562 may be defined as the second seed layer 561. By the fabricating process, the semiconductor device shown in FIGS. 17 and 18 may be fabricated.

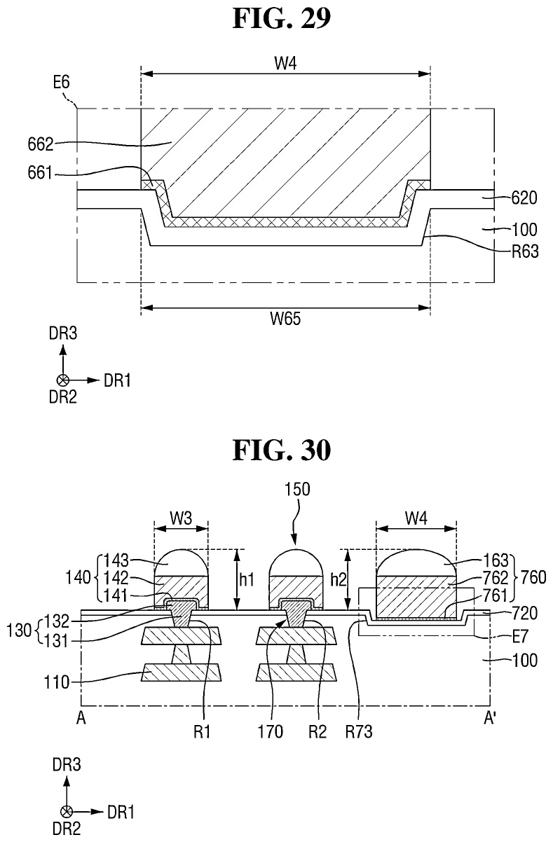

Hereinafter, a semiconductor device according to an example embodiment of the present disclosure will be described hereinafter with reference to FIGS. 28 and 29. A description will be given focusing on differences from the semiconductor device shown in FIGS. 1 to 3.

FIG. 28 is a cross-sectional view of a semiconductor device according to an example embodiment of the present disclosure. FIG. 29 is an enlarged view of portion E6 of FIG. 28.

Referring to FIGS. 28 and 29, in a semiconductor device according to an example embodiment of the present disclosure, a third recess R63 may be formed at a lower portion of a heat transfer bump 660 and at least a part of the heat transfer bump 660 may be disposed within the third recess R63.

For example, at the lower portion of the heat transfer bump 660, the third recess R63 may be formed to be recessed inwardly from the top surface of the substrate 100. That is, a bottom surface of the third recess R63 may be formed lower than the top surface of the substrate 100. For example, a width W4 of the heat transfer bump 660 in the first horizontal direction DR1 may be the same as a width W65 of the third recess R63 in the first horizontal direction DR1.

The passivation layer 620 may be disposed on the top surface of the substrate 100. Also, the passivation layer 620 may be disposed along sidewalls and a bottom surface of the third recess R63. A second seed layer 661 may be disposed on the passivation layer 620 in the third recess R63. In addition, the second seed layer 661 may be disposed on the top surface of the passivation layer 620 adjacent to the third recess R63. The second lower bump 662 may be disposed on the second seed layer 661. For example, at least a part of the second lower bump 662 may be disposed within the third recess R63.

Hereinafter, a semiconductor device according to an example embodiment of the present disclosure will be described hereinafter with reference to FIGS. 17 and 18. A description will be given focusing on differences from the semiconductor device shown in FIGS. 1 to 3.

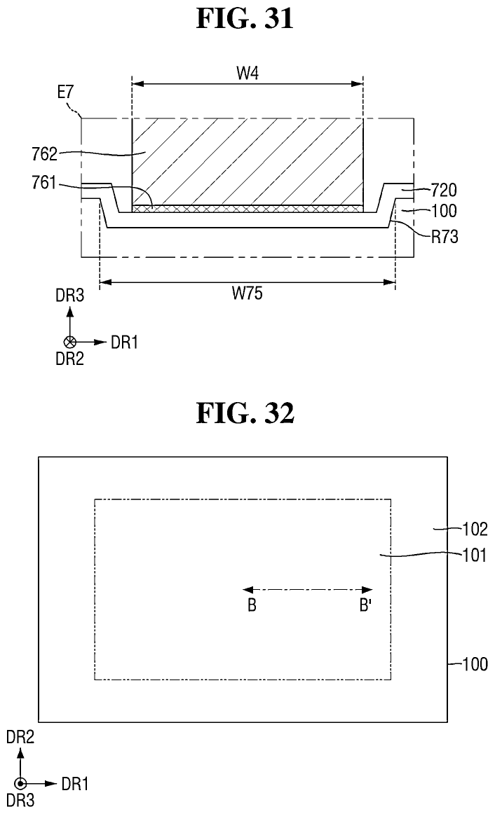

FIG. 30 is a cross-sectional view of a semiconductor device according to an example embodiment of the present disclosure. FIG. 31 is an enlarged view of portion E7 of FIG. 30.

Referring to FIGS. 30 and 31, in a semiconductor device according to an example embodiment of the present disclosure, a third recess R73 may be formed at a lower portion of a heat transfer bump 760 and at least a part of the heat transfer bump 760 may be disposed within the third recess R73.

For example, at the lower portion of the heat transfer bump 760, the third recess R73 may be formed to be recessed inwardly from the top surface of the substrate 100. That is, a bottom surface of the third recess R73 may be formed lower than the top surface of the substrate 100. For example, a width W4 of the heat transfer bump 760 in the first horizontal direction DR1 may be greater than a width W75 of the third recess R73 in the first horizontal direction DR1.

The passivation layer 720 may be disposed on the top surface of the substrate 100. Also, the passivation layer 720 may be disposed along sidewalls and a bottom surface of the third recess R73. A second seed layer 761 may be disposed on the passivation layer 720 in the third recess R73. For example, the second seed layer 761 may be spaced apart from the passivation layer 720 disposed on the sidewalls of the third recess R73. The second lower bump 762 may be disposed on the second seed layer 761. For example, at least a part of the second lower bump 762 may be disposed within the third recess R73. For example, in the third recess R73, the second lower bump 762 may be spaced apart from the passivation layer 720 disposed on the sidewalls of the third recess R73.

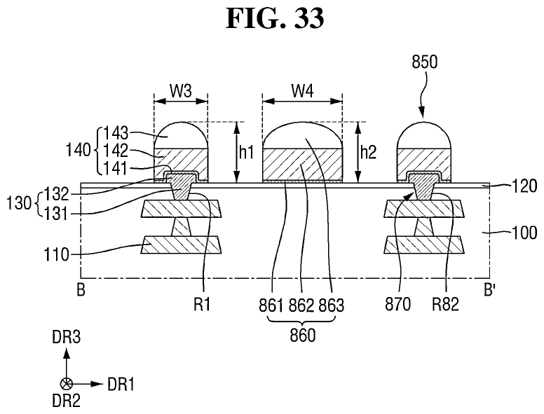

Hereinafter, a semiconductor device according to an example embodiment of the present disclosure will be described hereinafter with reference to FIGS. 32 and 33. A description will be given focusing on differences from the semiconductor device shown in FIGS. 1 to 3.

FIG. 32 is a schematic plan view of a semiconductor device according to an example embodiment of the present disclosure. FIG. 33 is a cross-sectional view taken along line B-B′ of FIG. 32.

Referring to FIGS. 32 and 33, in a semiconductor device according to an example embodiment of the present disclosure, a heat transfer bump 860 may be disposed between a first signal bump 140 and a second signal bump 850.

For example, each of the first signal bump 140, the heat transfer bump 860, and the second signal bump 850 may be disposed on a first region 101, which is the central region of the substrate 100. For example, although not illustrated in FIG. 33, another heat transfer bump may be disposed on a second region 102, which is an edge of a substrate 100.

For example, the heat transfer bump 860 may be spaced apart from the first signal bump 140 in the first horizontal direction DR1. The heat transfer bump 860 may include a second seed layer 861, a second lower bump 862, and a second upper bump 863 which are sequentially stacked on a top surface of a passivation layer 120. The heat transfer bump 860 shown in FIG. 33 may have the same structure as that of the heat transfer bump 160 shown in FIG. 2.

For example, the second recess R82 may be spaced apart from a first recess R1 in the first horizontal direction DR1. For example, the first recess R1 may be formed on a first side of the heat transfer bump 860. The second recess R82 may be formed on a second side that faces the first side of the heat transfer bump 860 in the first horizontal direction DR1.

A second post 870 may be disposed within the second recess R82. In addition, at least a part of the second post 870 may protrude from the top surface of the passivation layer 120 in the vertical direction DR3. The second post 870 may be spaced apart from a first post 130 in the first horizontal direction DR1. The second post 870 may have the same structure as that of the first post 130.

A second signal bump 850 may be spaced apart from the heat transfer bump 860 in the first horizontal direction DR1. The second signal bump 850 may be disposed on the second post 870. The second signal bump 850 may have the same structure as that of the first signal bump 140.

While the present disclosure has been particularly shown and described with reference to some example embodiments thereof and using specific terms, these example embodiments are provided so that this disclosure will fully convey the inventive concepts of the present disclosure, and not for purposes of limitation. Thus, it will be obvious to one of ordinary skill in the art that various changes and other equivalents may be made therein. Therefore, the scope of the present disclosure is defined not by the detailed description of the present disclosure but by the appended claims.

What is claimed:

1. A semiconductor device comprising:
a substrate;
a wiring pattern disposed in the substrate;
a passivation layer disposed on the substrate;
the passivation layer and the substrate including a first recess defined therein, the first recess penetrating a part of the passivation layer and a part of the substrate and extending toward the wiring pattern;
a post connected to the wiring pattern, the post comprising a first portion and a second portion, the first portion disposed within the first recess, the second portion disposed on the first portion and protruding from a top surface of the passivation layer in a vertical direction;
a signal bump comprising a first seed layer disposed on the post, a first lower bump disposed on the first seed layer, and a first upper bump disposed on the first lower bump; and
a heat transfer bump being spaced apart from the signal bump in a horizontal direction and electrically insulated from the wiring pattern, the heat transfer bump comprising a second seed layer disposed on the passivation layer, a second lower bump disposed on the second seed layer, and a second upper bump disposed on the second lower bump,
wherein a width of the heat transfer bump in the horizontal direction is greater than a width of the signal bump in the horizontal direction.

2. The semiconductor device of claim 1, wherein a first height of the signal bump from the top surface of the passivation layer to a topmost point of the first upper bump is same as a second height of the heat transfer bump from the top surface of the passivation layer to a topmost point of the second upper bump.

3. The semiconductor device of claim 1, wherein the second seed layer is lower than a portion of the first seed layer that is disposed on a top surface of the post.

4. The semiconductor device of claim 1, wherein the post and the first lower bump include a same material, and the first seed layer includes a material different from that of the post and that of the first lower bump.

5. The semiconductor device of claim 4, wherein each of the post and the first lower bump includes nickel (Ni), and the first seed layer includes copper (Cu).

6. The semiconductor device of claim 1, wherein an entire bottom surface of the second seed layer is in contact with the passivation layer.

7. The semiconductor device of claim 1, wherein the substrate comprises a first region in which the signal bump is disposed and a second region which surrounds the first region and has the heat transfer bump disposed therein.

8. The semiconductor device of claim 1, wherein an entirety of the second seed layer is higher than a top surface of the substrate.

9. The semiconductor device of claim 1, further comprising:
the substrate including a second recess defined at a lower portion of the heat transfer bump, the second recess recessed inwardly from a top surface of the substrate,
wherein at least a part of the heat transfer bump is disposed within the second recess.

10. The semiconductor device of claim 9, wherein the width of the heat transfer bump in the horizontal direction is greater than a width of the second recess in the horizontal direction.

11. The semiconductor device of claim 9, wherein the width of the heat transfer bump in the horizontal direction is smaller than a width of the second recess in the horizontal direction.

12. The semiconductor device of claim 1, wherein the width of the heat transfer bump in the horizontal direction is greater than a width of the second portion of the post in the horizontal direction.

13. A semiconductor device comprising:
a substrate;
a wiring pattern disposed in the substrate;
a passivation layer disposed on the substrate;
the passivation layer and the substrate including a first recess defined therein, the first recess penetrating a part of the passivation layer and a part of the substrate and extending toward the wiring pattern;
a first post connected to the wiring pattern and comprising a first portion and a second portion, the first portion disposed within the first recess, the second portion disposed on the first portion and protruding from a top surface of the passivation layer in a vertical direction;
a first signal bump disposed on the first post; and
a heat transfer bump disposed on the passivation layer, spaced apart from the first signal bump in a horizontal direction, and electrically insulated from the wiring pattern,
wherein a width of the heat transfer bump in the horizontal direction is greater than a width of the first signal bump in the horizontal direction, and
wherein a first height from the top surface of the passivation layer to a topmost point of the first signal bump is same as a second height from the top surface of the passivation layer to a topmost point of the heat transfer bump.

14. The semiconductor device of claim 13, wherein
the first signal bump comprises a first seed layer disposed on the first post, a first lower bump disposed on the first seed layer, and a first upper bump disposed on the first lower bump,
the heat transfer bump comprises a second seed layer disposed on the passivation layer, a second lower bump disposed on the second seed layer, and a second upper bump disposed on the second lower bump, and
the second seed layer is lower than a portion of the first seed layer that is on a top surface of the first post.

15. The semiconductor device of claim 13, wherein the width of the first signal bump in the horizontal direction is same as a width of the second portion of the first post in the horizontal direction.

16. The semiconductor device of claim 13, wherein the width of the first signal bump in the horizontal direction is smaller than a width of the second portion of the first post in the horizontal direction.

17. The semiconductor device of claim 13, further comprising:
the passivation layer and the substrate including a second recess defined therein to be spaced apart from the first recess in the horizontal direction, the second recess penetrating a part of the passivation layer and a part of the substrate and extending toward the wiring pattern;
a second post connected to the wiring pattern and being spaced apart from the first post in the horizontal direction and disposed within the second recess, the second post protruding at least partially from the top surface of the passivation layer in the vertical direction; and
a second signal bump disposed on the second post,
wherein the heat transfer bump is disposed between the first signal bump and the second signal bump.

18. A semiconductor device comprising:
a substrate;
a wiring pattern disposed in the substrate;
a passivation layer disposed on the substrate;
the passivation layer and the substrate including a recess defined therein, the recess penetrating a part of the passivation layer and a part of the substrate and extending toward the wiring pattern;
a post connected to the wiring pattern and comprising a first portion and a second portion, the first portion disposed within the recess and the second portion disposed on the first portion and protruding from a top surface of the passivation layer in a vertical direction;
a signal bump comprising a first seed layer disposed on the post, a first lower bump disposed on the first seed layer, and a first upper bump disposed on the first lower bump; and
a heat transfer bump being spaced apart from the signal bump in a horizontal direction and electrically insulated from the wiring pattern, the heat transfer bump comprising a second seed layer disposed on the passivation layer, a second lower bump disposed on the second seed layer, and a second upper bump disposed on the second lower bump,
wherein a width of the heat transfer bump in the horizontal direction is greater than a width of the second portion of the post in the horizontal direction,
wherein the post and the first lower bump include a same material,
wherein the first seed layer includes a different material from each of the post and the first lower bump, and
wherein the second seed layer is lower than a portion of the first seed layer that is on a top surface of the post.

19. The semiconductor device of claim 18, wherein the width of the heat transfer bump in the horizontal direction is greater that a width of the signal bump in the horizontal direction.

20. The semiconductor device of claim 18, wherein a first height of the signal bump from the top surface of the passivation layer to a topmost point of the first upper bump is same as a second height of the heat transfer bump from the top surface of the passivation layer to a topmost point of the second upper bump.
